(19) United States
(12) Patent Application Publication
(10) Pub. No.: US 2007/0048936 A1
(43) Pub. Date: Mar. 1, 2007

(54) Method for forming memory cell and periphery circuits

(76) Inventors: Jongoh Kim, Hsinchu (TW); Cheng-Jye Liu, Jhongli City (TW)

Correspondence Address: J C PATENTS, INC., 4 VENTURE, SUITE 250, IRVINE, CA, 92618, US

(21) Appl. No.: 11/217,281

(22) Filed: Aug. 31, 2005

(51) Int. Cl. H01L 21/336

(52) U.S. Cl. 438/257

(57) ABSTRACT

A method for forming a memory cell and periphery circuit includes providing a substrate with a peripheral circuit region and a memory cell region. A mask layer is formed on the substrate to define multiple active regions in the peripheral circuit region and to define multiple channel regions in the memory cell region. Multiple field oxide layers are formed between the active areas, and Dopants are implanted in the substrate between the channel regions. Multiple inter-cell isolation layers are formed between the channel regions and the dopants are driven in the substrate to form buried diffusion regions. The mask layer is removed. A layer of electricity-storage material and multiple word lines are formed on the substrate in the memory cell region.

### BACKGROUND OF THE INVENTION

1. Field of the Invention

This invention generally relates to a method for forming a transistor device, and especially to a method for forming memory cells and simultaneously forming memory cells and periphery circuits.

2. Description of Related Art

The memory, which is used for storing electronic data, is one of the important components in the semiconductor. In genera, the memory that can store electronic data without periphery power supply is called the Non-Volatile Memory device.

The current non-volatile memory comprises an erasable programmable ROMs (EPROMs), electrically erasable programmable ROMs (EEPROMS) and Flash memory. These memories can be operated by channel hot electron (CHE) injecting or fowler-nordheim (F-N) tunneling field emission mechanism.

Take the flash memory as an example, which comprises a stack-type gate structure on a semiconductor substrate, wherein the stack-type gate structure comprises a tunneling oxide layer, a polysilicon floating gate over the tunneling oxide layer, a polysilicon control gate on the polysilicon floating gate, and a interpoly dielectric layer between the floating gate and the control gate.

In recent development of non-volatile memory, a localized trapped charge device has been presented, which is called nitride read-only memory. With multiple advantages, the nitride read-only memory provides a performance that surpasses other memories which mainly comprises a floating gate and which stores electrons in the floating gate with electric conductivity.

FIGS. 1A-1C are schematic cross-sectional views of a manufacturing process for forming a conventional nitride read-only memory cell, whereas FIG. 1D is a partial enlarged view of FIG. 1C, for describing some disadvantages in the conventional nitride read-only memory.

As shown in FIG. 1A, a substrate 100 is provided, then a silicon oxide/silicon nitride/silicon oxide layer 110 (ONO layer) is formed on the substrate 100. The ONO layer comprises a top oxide layer 112, a nitride layer 114 and a bottom oxide layer 116 with similar thickness.

Further, as shown in FIG. 1B, a part of the ONO layer is removed for defining a plurality of tunnel regions 120 at the substrate 100. Then, dopants 130 are further implanted in the substrate 100 between the tunnel regions 120.

Furthermore, as shown in FIG. 1C, a buried drain oxide (BDOX) layer 140 is formed between the tunnel regions 120 by a thermal oxidation process, so that the dopants 130 are driven in the substrate 100 to form buried bit lines 150. Finally, word lines 160 vertical to the buried bit lines 150 are formed on the substrate 100 and the ONO layer 110; that is, the conventional nitride read-only memory cell is formed.

However, the above-mentioned manufacturing process has the following disadvantage. Please refer to FIG. 1D, which is an enlarged view of the part D in FIG. 1C.

1. Because the thickness ratio of the nitride layer to the oxide layer in the ONO layer 110 affects the length of the bird's beak 142 in the buried drain oxide layer 140, and the effect is that the thickness ratio of the nitride layer to the oxide layer is larger, the length of the bird's beak is longer. However, when forming the buried drain oxide layer 140, since the thickness among the nitride layer 114 and the oxide layer 112, 116 of the ONO layer 100 are not much different, such that the thickness ratio of the nitride layer to the oxide layer is about 1. Therefore, it is impossible to further shrink the length of the bird's beak 142 in the buried drain oxide layer 140, which becomes an obstacle in developing minimized devices.

2. When forming the buried drain oxide layer 140, the buried drain oxide layer 140 will substantially bulge; therefore the bottom oxide layer 112 of the ONO layer 110 will be damaged by stress.

3. After the dopants 130 are implanted in the substrate 100 between the tunnel regions 120 shown in FIG. 1B, if a pocket implant is needed, a tilt ion implant process will be utilized for implanting other dopants in the substrate 100, which would damage the nitride oxide layer 114 of the already formed ONO layer 110.

4. After forming the buried drain oxide layer 140, due to the bulge of the ONO layer 110, the nitride oxide layer 114 of the ONO layer 110 can be exposed to touch and therefore electrically connect with the formed word line 160, thus decreasing the reliability of the whole device.

### SUMMARY OF THE INVENTION

An object of the present invention is to provide a method for forming memory cell capable of improving the length of the bird's beak in a conventional inter-cell isolation layers in the trend of minimized devices.

Another object of the present invention is to provide a method for forming memory cell and periphery circuit, where the memory cell with more reliability than the conventional memory cell can be manufactured in cooperation with the manufacturing process of the periphery circuit.

The present invention provides a method for forming memory cell. The method comprises providing a substrate, and then forming a liner layer and a mask layer on the substrate to define a plurality of tunnel regions on the substrate. A plurality of dopants are implanted in the substrate between the tunnel regions, and a plurality of inter-cell isolation layers are formed on the substrate between the channel regions, such that the dopants are driven in the substrate to form a plurality of buried diffusion regions. The mask layer and the liner layer are removed, a layer of electricity-storage material is formed on the substrate, and a plurality of word lines are formed on the layer of electricity-storage material.

The present invention also provides a method for forming memory cell and periphery circuit. First, a substrate is provided, which has a periphery circuit region and a memory cell region thereon. A liner layer is formed on the substrate, and then a mask layer is formed on the liner layer to define a plurality of active regions in the memory cell region. Thereafter, multiple field oxide layers are formed on the substrate between the active regions and then the mask layer is utilized to define a plurality of tunnel regions at the periphery circuit region. Multiple dopants are implanted in the substrate between the tunnel regions. Further, a plurality of inter-cell isolation layers are formed on the substrate between the channel regions, and the dopants are driven in the substrate to form a plurality of buried diffusion regions. Then, the mask layer and the liner layer are removed, a layer of electricity-storage material is formed on substrate at the memory cell region, and a plurality of word lines are formed on the substrate and the layer of electricity-storage material.

After the dopants are implanted in the substrate between the tunnel regions, the pocket implant can be performed, and because the layer of electricity-storage material is not yet formed, the tilt ion implant process for the pocket implant at the edge of the layer of electricity-storage material near the bit lines, which may damage the nitride oxide layer of the layer of electricity-storage material already formed, would not be performed.

Since the inter-cell isolation layers is implanted and formed before the layer of electricity-storage material is formed, the stress, resulted from the bulging of the inter-cell isolation layers in the conventional technology, would not force the layer of electricity-storage material at the edge of the inter-cell isolation layers to become warped, or damage the bottom silicon oxide layer of the layer of electricity-storage material.

Since the present invention utilizes the structure of the inter-cell isolation layers and the inter-cell isolation layers is implanted and formed before the layer of electricity-storage material is formed, the layer of electricity-storage material would not become warped to expose the mask layer of the layer of electricity-storage material to electrically connect with the word line, so that the reliability of the whole device is increased.

Since the inter-cell isolation layers is first formed in the present invention, the mask layer when forming the field oxide layer can be used as masks for forming the inter-cell isolation layers, and because the thickness of the mask layer is larger than the thickness of a liner layer, the length of the bird's beak of the inter-cell isolation layers can be reduced.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIGS. 1A-1C are schematic cross-sectional views of a conventional manufacturing process for forming a nitride read-only memory cell, whereas FIG. 1D is a partial enlarged view of FIG. 1C.

FIGS. 2A-2C are schematic cross-sectional views of a manufacturing process for forming memory cells according to an embodiment of the present invention.

FIGS. 3A-3C are schematic cross-sectional views of a manufacturing process for forming memory cells and periphery circuits according to another embodiment of the present invention.

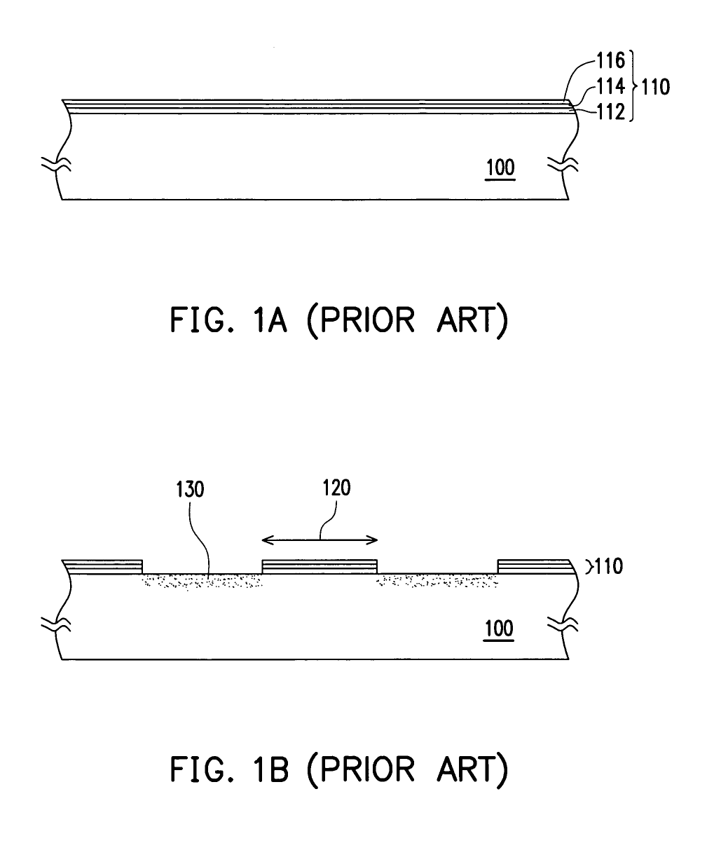

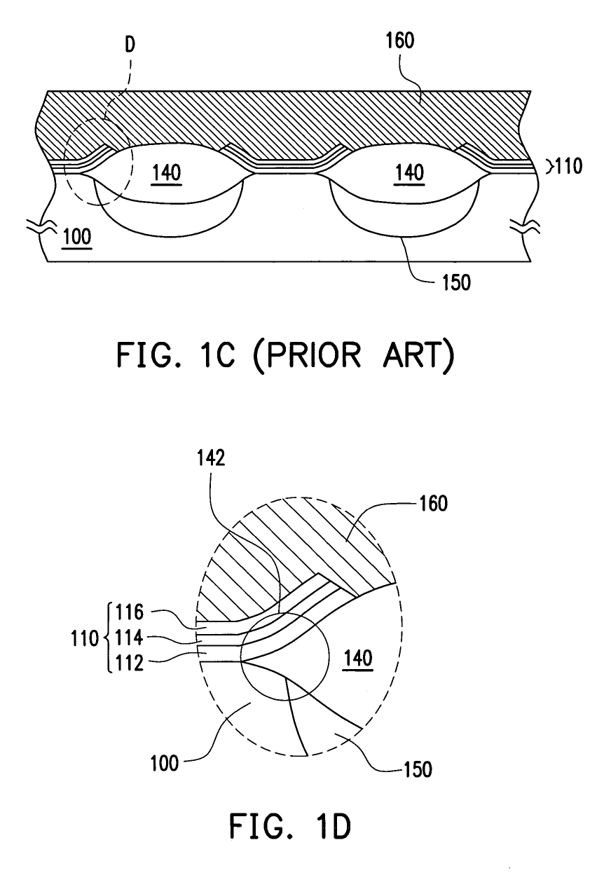

### DESCRIPTION OF THE EMBODIMENTS

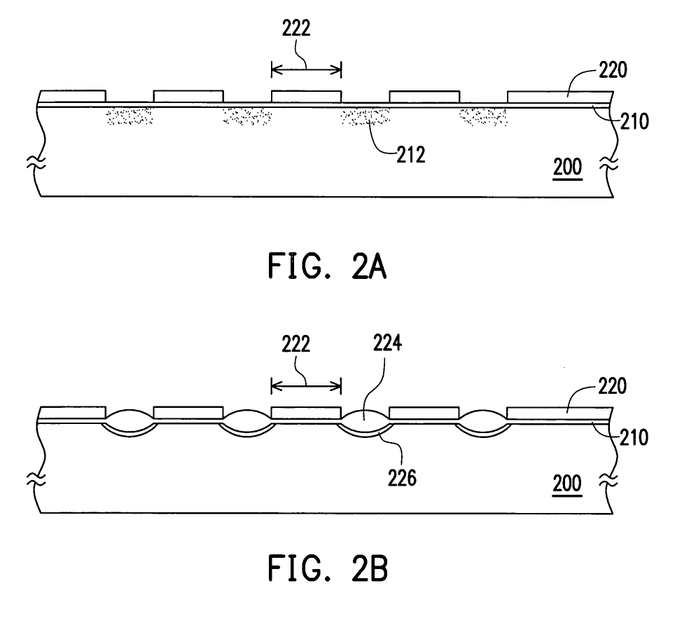

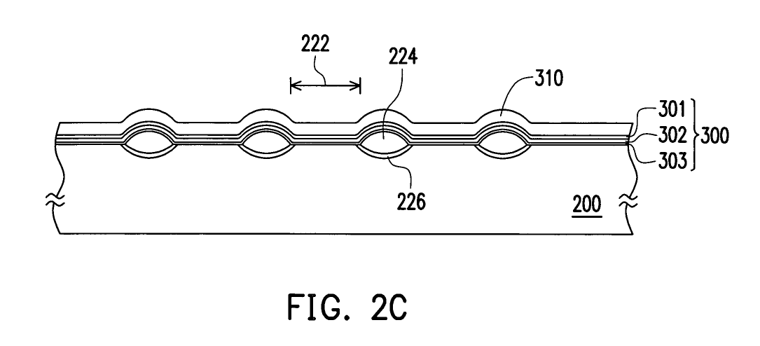

FIG. 2A-2C are schematic cross-sectional views of a manufacturing process for forming memory cells according to an embodiment of the present invention.

First, referring to FIG. 2A, a substrate 200 is provided, then a liner layer 210 can be formed on the substrate 200, for example, the liner layer 210 is pad oxide layer. Next, a mask layer 220 is formed on the liner layer 210 in order to define a plurality of tunnel regions 222 on the substrate 200; for example, a material of the mask layer 220 is dielectric such as silicon nitride. Furthermore, a plurality of dopants 212, such as boron or arsenic, is implanted in the substrate 200 between the tunnel regions 222. After implanting the dopants 212, a tilt ion implant process can be optionally performed for pocket implant (not shown).

Further, as shown in FIG. 2B, using the liner layer 210 and the mask layer 220 as masks, a plurality of inter-cell isolation layers 224 is formed on the substrate 200 between the channel regions 222. At the same time, the dopants 212 are driven in the substrate 200 (referring to FIG. 2A), and a plurality of buried diffusion regions 226 are formed. And, the plurality of the inter-cell isolation layers 224 can be oxide layers, buried bit line oxide layers or buried drain oxide layers, and the buried diffusion regions 226 can be used as buried bit lines.

Next, referring to FIG. 2C, the mask layer 220 is removed, and the liner layer 210 is removed, simultaneously. Afterwards, a layer of electricity-storage material 300 is formed on the substrate 200, wherein the electricity-storage material includes oxide/nitride/oxide (ONO) or other suitable material enabling of trapping or storing charges. In this case, for example, the method for forming the layer of electricity-storage material 300 on the substrate 200 is generally by forming a bottom oxide layer 303 on the substrate 200, forming a nitride layer 302 on the bottom oxide layer 303, and then forming a top oxide layer 303 on the nitride layer 302. In addition, when the distance between the memory cells decreases gradually, in order to avoid the affect of the high-temperature manufacturing process on the already formed buried diffusion regions 226, the In Situ Steam Generation (ISSG) method, which has a lower process temperature, can be utilized for forming the bottom oxide layer 303, and the High Temperature Oxidation (HTO) or Slot Plane Antenna (SPA) method, which also have a lower process temperature, can be utilized for forming the top oxide layer 303. In the SPA method, slot plane is used to generate uniform plasma in order to form oxide or silicon nitride layers, so the temperature is usually lower than conventional furnace process. Then, a plurality of word lines 310 are formed on the layer of electricity-storage material 300, and the word lines 310 are vertical to the bit lines 226, for example.

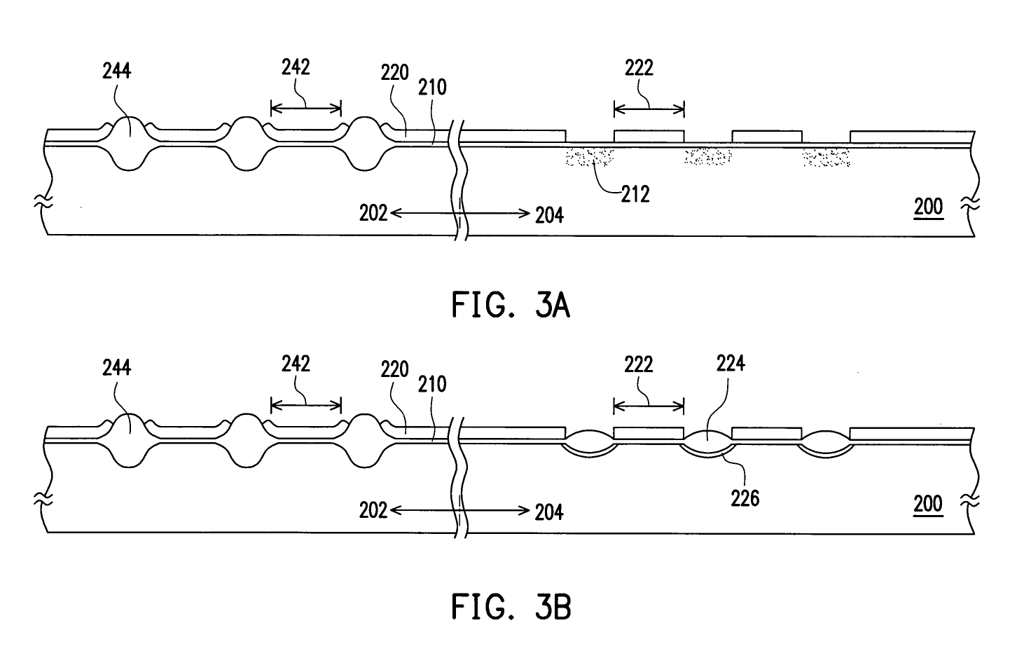

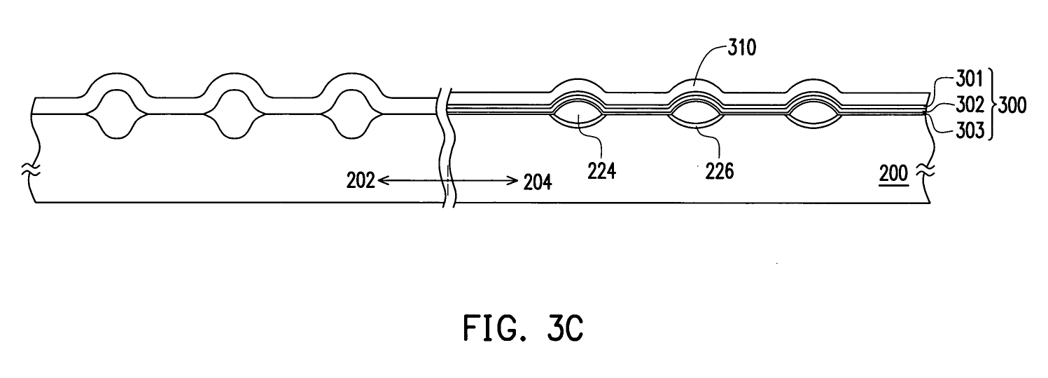

FIGS. 3A-3C are schematic cross-sectional views of a manufacturing process for forming memory cells and periphery circuit according to another embodiment of the present invention. And, the same reference labels with the above embodiment represent the same or similar elements.

First, referring to FIG. 3A, a substrate 200 is provided, wherein the substrate 200 comprises a periphery circuit region 202 and a memory cell region 204. Then, a liner layer 210 can be formed on the substrate 200 and a material of the liner layer 210 is such as silicon oxide. A mask layer 220 is then formed on the liner layer 210 so as to define a plurality of active regions 242. Then, using the mask layer 220 as a mask, a plurality of field oxide layers 244 are formed on the substrate 200 between the active regions 242, wherein the method for forming the field oxide layers 244 can include a thermal oxidation process. After forming the field oxide layers 244 on the substrate 200 between the active regions 242, the mask layer 220 is utilized again to define a plurality of tunnel regions 222 on the memory cell region 240. A plurality of dopants 212, such as boron or arsenic, is then implanted in the substrate 200 between the tunnel regions 222. After implanting the dopants 212, a tilt ion implant process can be optionally utilized further for pocket implant (not shown).

Further, in FIG. 3B, using the mask layer 210 as a mask, a plurality of inter-cell isolation layers 224 are formed on the substrate 200 between the channel regions 222 by the thermal oxidation process, for example, and the dopants 212 shown in FIG. 3A are driven in the substrate 200 to form a plurality of buried diffusion regions 226. The plurality of inter-cell isolation layers 224 include oxide layers, buried bit line oxide layers or buried drain oxide layers. The plurality of buried diffusion regions 226 can be used as buried bit lines.

Then, in FIG. 3C, the mask layer 220 is removed completely and meantime the liner layer 210 can be also removed. A layer of electricity-storage material 300 is further formed on the substrate 200 at the memory cell region 204, wherein the manufacturing process is by forming a bottom oxide layer 303, a nitride layer 302 and a top oxide layer 303 sequentially on the substrate 200, then removing the layer of electricity-storage material 300 outside the memory cell region 204. In order to avoid the affect of the high-temperature manufacturing process on the already formed buried diffusion regions 226, the ISSG method, which has a lower temperature, can be utilized for forming the bottom oxide layer 303, and the HTO or the SPA, which also have lower temperature, can be utilized for forming the top oxide layer 303. Then, a plurality of word lines 310 are formed on substrate 200 and the layer of electricity-storage material 300, wherein the method for forming the word lines 310, for example, is by covering a conductive layer on the substrate 200 and the layer of electricity-storage material 300, the patterning the conductive layer for forming the word lines 310 vertical to the bit lines 226. Meanwhile, the above-mentioned conductive layer, which remains at the periphery circuit region 202, can be utilized as gates, for example.

In summary, the present invention has at least the following advantages:

1. Since the method according to the present invention is to utilize the mask layer for forming the field oxide layer and the liner layer as the mask for forming the inter-cell isolation layers, and because the thickness of the mask layer is larger than the thickness of the liner layer, the length of the bird's beak of the inter-cell isolation layers can be reduced.

2. Since the inter-cell isolation layers is formed before the formation of the layer of electricity-storage material, the stress, resulted from the bulging of the inter-cell isolation layers in the conventional technology, would not force the layer of electricity-storage material at the edge of the inter-cell isolation layers to become warped, or damage the bottom silicon oxide layer of the layer of electricity-storage material.

3. Since the dopants are implanted in the substrate between the tunnel regions before forming the layer of electricity-storage material, the edge of the layer of electricity-storage material would not be damaged even if the pocket implant is performed.

4. Since the structure of the inter-cell isolation layers in the present invention does not expose the layer of electricity-storage material, the word line does not be electrically connect with the electricity-storage material, so that the reliability of the memory can be increased.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

What is claimed is:

1. A method for forming a memory cell, comprising:
providing a substrate;
forming a liner layer on the substrate;
forming a mask layer on the liner layer to define a plurality of tunnel regions in the substrate;
implanting a plurality of dopants in the substrate between the tunnel regions;
forming a plurality of inter-cell isolation layers on the substrate between the channel regions such that the dopants are driven in the substrate to form a plurality of buried diffusion regions;
removing the mask layer and the liner layer;
forming a layer of electricity-storage material on the substrate to cover the substrate and the inter-cell isolation layers; and
forming a plurality of word lines on the layer of electricity-storage material.

2. The method for forming a memory cell of claim 1, wherein the step of forming the inter-cell isolation layers on the substrate between the tunnel regions comprises performing a thermal oxidation process.

3. The method for forming a memory cell of claim 1, wherein the plurality of inter-cell isolation layers comprise oxide layers, buried bit line oxide layers or buried drain oxide layers.

4. The method for forming a memory cell of claim 1, wherein the thickness range of the liner layer is 100 to 250 angstroms.

5. The method for forming a memory cell of claim 1, wherein a material of the formed mask layer comprises silicon nitride, and a material of the formed liner layer comprises silicon oxide.

6. The method for forming a memory cell of claim 1, wherein the dopants, which are implanted in the substrate between the tunnel regions, comprise boron or arsenic.

7. The method for forming a memory cell of claim 1, wherein, after the dopants are implanted in the substrate between the tunnel regions, the next step comprises a pocket implant process.

8. The method for forming a memory cell of claim 1, wherein the step of forming a plurality of word lines comprises forming a plurality of word lines vertical to the plurality of buried diffusion regions.

9. The method for forming a memory cell of claim 1, wherein the plurality of buried diffusion regions comprise buried bit lines.

10. The method for forming a memory cell of claim 1, wherein the electricity-storage material comprises oxide/nitride/oxide (ONO).

11. The method for forming a memory cell of claim 1, wherein the method for forming the layer of electricity-storage material on the substrate comprises:
forming a bottom oxide layer on the substrate;
forming a nitride layer on the bottom oxide layer; and
forming a top oxide layer on the nitride layer.

12. The method for forming a memory cell of claim 11, wherein the method for forming the bottom oxide layer comprises an In Situ Steam generation (ISSG) method.

13. The method for forming a memory cell of claim 11, wherein the method for forming the top oxide layer includes the High Temperature Oxidation (HTO) or the Slot Plane Antenna (SPA) method.

14. A method for forming a memory cell and periphery circuit, comprising:
providing a substrate, which has a periphery circuit region and a memory cell region;
forming a liner layer on the substrate;
forming a mask layer on the liner layer to define a plurality of active regions;
forming a plurality of field oxide layers on the substrate between the active regions;
utilizing the mask layer on the substrate to define a plurality of tunnel regions;
implanting a plurality of dopants in the substrate between the tunnel regions;
forming a plurality of inter-cell isolation layers on the substrate between the channel regions such that the dopants are driven in the substrate to form a plurality of buried diffusion regions;
removing the mask layer and the liner layer;
forming a layer of electricity-storage material on the substrate at the memory cell region; and
forming a plurality of word lines on the substrate and the layer of electricity-storage material.

15. The method for forming a memory cell and periphery circuit of claim 14, wherein the step for forming the field oxide layers on the substrate between the active regions comprises performing a thermal oxidation process.

16. The method for forming a memory cell and periphery circuit of claim 14, wherein the step for forming the inter-cell isolation layers on the substrate between the tunnel regions comprises a thermal oxidation process.

17. The method for forming a memory cell and periphery circuit of claim 14, wherein the plurality of inter-cell isolation layers comprise oxide layers, buried bit line oxide layers or buried drain oxide layers.

18. The method for forming a memory cell and periphery circuit of claim 14, wherein before the step of forming a mask layer on the substrate further comprises forming a liner layer on the substrate.

19. The method for forming a memory cell and periphery circuit of claim 15, wherein a material of the formed mask layer comprises silicon nitride, and a material of the formed liner layer comprises silicon oxide.

20. The method for forming a memory cell and periphery circuit of claim 14, wherein the dopants, which are implanted in the substrate between the tunnel regions, comprises boron or arsenic.

21. The method for forming a memory cell and periphery circuit of claim 14, wherein, after the dopants are implanted in the substrate between the tunnel regions, the next step comprises a pocket implant process.

22. The method for forming a memory cell and periphery circuit of claim 14, wherein the plurality of buried diffusion regions comprise buried bit lines.

23. The method for forming a memory cell and periphery circuit of claim 14, wherein the step of forming a plurality of word lines comprises forming a plurality of word lines vertical to the plurality of buried diffusion regions.

24. The method for forming a memory cell and periphery circuit of claim 14, wherein the electricity-storage material comprises ONO.

25. The method for forming a memory cell and periphery circuit of claim 14, wherein the method for forming the layer of electricity-storage material on the substrate comprises
forming a bottom oxide layer on the substrate;
forming a nitride layer on the bottom oxide layer; and
forming a top oxide layer on the nitride layer.

26. The method for forming a memory cell and periphery circuit of claim 25, wherein the method for forming the bottom oxide layer comprises the ISSG method.

27. The method for forming a memory cell and periphery circuit of claim 25, wherein the method for forming the top oxide layer comprises the HTO or the SPA method.
